(19) United States
(12) Patent Application Publication
(10) Pub. No.: US 2025/0169256 A1
(43) Pub. Date: May 22, 2025

(54) Display Device and Method of Manufacturing a Display Device

(71) Applicant: LG Display Co., Ltd., Seoul (KR)

(72) Inventor: Dong Geun Bae, Paju-si (KR)

(21) Appl. No.: 18/922,783

(22) Filed: Oct. 22, 2024

(30) Foreign Application Priority Data
Nov. 20, 2023 (KR) 10-2023-0160826

(51) Int. Cl. H01L 33/62; H01L 25/16; H01L 33/00; H01L 33/58

(52) U.S. Cl. CPC H10H 20/857; H01L 25/167; H10H 20/018; H10H 20/855; H10H 20/0363; H10H 20/0364

(57) ABSTRACT

The disclosure relates to a display device and a method of manufacturing a display device. A display device according to embodiments of the present specification includes a substrate including a display area and a non-display area, a driving circuit part disposed in the display area on the substrate; a plurality of planarization layers disposed on the driving circuit part, and a plurality of pixels disposed on the plurality of planarization layers in the display area, wherein the plurality of pixels include a plurality of first light-emitting element areas and a plurality of second light-emitting element areas, and a first insulating layer is disposed in the first light-emitting element area and the second light-emitting element area, and the first insulating layer may have different heights in the first light-emitting element area and the second light-emitting element area.

### CROSS-REFERENCE TO RELATED APPLICATION

This application claims priority to and the benefit of Republic of Korea Patent Application No. 10-2023-0160826, filed on Nov. 20, 2023, which is hereby incorporated by reference in its entirety.

### TECHNICAL FIELD

The present specification relates to a display device. Specifically, the present specification relates to a display device and a manufacturing method for preventing or at least reducing defects caused by contact between a first electrode and a second electrode in a display device using a micro light-emitting diode.

### BACKGROUND

Liquid crystal display devices and organic light-emitting display devices are used as flat display devices.

Organic light-emitting display devices have advantages such as improved luminous efficiency, fast response speed, and wide viewing angle compared to liquid crystal display devices. However, organic light-emitting display devices still have low luminous efficiency and are susceptible to moisture because they contain organic substances, which may reduce reliability and lifetime.

Recently, micro light-emitting diode display devices, which are inorganic light-emitting display devices, have been proposed.

The micro light-emitting diode display devices implement images by arranging inorganic light-emitting diodes with a size of 100 micrometers (μm) or less in each pixel. In the micro light-emitting diode display devices, micro light-emitting diodes grown on a single crystal substrate may be arranged on an array substrate of the display device and electrodes may be connected.

### SUMMARY

An array substrate is provided by forming pixel driving circuit parts and connection wiring on a substrate of a display device.

A first electrode connected to a micro light-emitting diode element (hereinafter, referred to as a light-emitting element) may be disposed on the array substrate of the display device, the light-emitting element may be disposed on the array substrate, and then a second electrode may be disposed on the light-emitting element.

A light-emitting element grown on a single crystal substrate may be disposed on an array substrate by a transfer process.

After the light-emitting element is disposed, the second electrode may connect the light-emitting element and a pixel driving circuit to transmit a power voltage.

During the transfer process, there is an instance where the light-emitting element is not transferred to a predetermined position on the array substrate.

If the light-emitting element is not disposed, the first electrode below the lighting-emitting element and the second electrode may be in contact with each other to be electrically connected, which may cause a short.

Accordingly, the inventors of the present specification have invented a display device and a manufacturing method thereof capable of improving reliability by preventing a short between a second electrode and a first electrode disposed below the second electrode in a non-transferred area of a light-emitting element.

Problems of the present specification are not limited to the above-mentioned problems, and other problems which are not mentioned will be clearly understood by those skilled in the art from the following disclosure.

A display device according to embodiments of the present specification may include a substrate including a display area and a non-display area, a driving circuit part (which can be also referred to as a driving circuit unit) disposed in the display area on the substrate; a plurality of planarization layers disposed on the driving circuit part, and a plurality of pixels disposed on the plurality of planarization layers in the display area, wherein the plurality of pixels include a plurality of first light-emitting element areas and a plurality of second light-emitting element areas, and a first insulating layer is disposed in the first light-emitting element area and the second light-emitting element area, and the first insulating layer may have different heights in the first light-emitting element area and the second light-emitting element area.

A method of manufacturing a display device according to embodiments of the present specification may include preparing a substrate including a display area and a non-display area, forming a driving circuit part and a plurality of planarization layers on the substrate, forming a protrusion on the plurality of planarization layers, forming a first connection electrode and a second connection electrode in a first light-emitting element area and a second light-emitting element area disposed on the protrusion, disposing a light-emitting element on one of the first connection electrode and the second connection electrode, and disposing a lens respectively on an upper portion of the other one of the first connection electrode and the second connection electrode and on an upper portion of the light-emitting element, wherein a first insulating layer may be disposed on the first light-emitting element area and the second light-emitting element area.

Another display device according to embodiments of the present specification may include: a substrate including a display area and a non-display area; a driving circuit part disposed on the substrate; a plurality of planarization layers disposed on the driving circuit part; and a plurality of pixels disposed on the plurality of planarization layers in the display area, wherein the plurality of pixels include a plurality of first light-emitting element areas and second light-emitting element areas, a first connection electrode, a first light-emitting element disposed on the first connection electrode, a first lens disposed on the first light-emitting element, and a second electrode disposed on the first lens are disposed in the first light-emitting element area, and a second connection electrode, a second lens disposed on the second connection electrode, and a second electrode disposed on the second lens are disposed in the second light-emitting element area.

According to embodiments of the present specification, the driving reliability of the display device may be improved by preventing an electrical short between the second electrode and the first electrode below the second electrode in the non-transferred area of the light-emitting element.

According to embodiments of the present specification, the light efficiency of the light-emitting element may be increased by disposing a lens on an upper portion of the light-emitting element.

The effects of this specification are not limited to the above effects, and other effects, which are not mentioned herein, will be obvious to those skilled in the art from the following description.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a plan view illustrating a display device according to one embodiment of the present specification;

FIG. 2 is a plan view of a structure in which wirings of a pixel of FIG. 1 are disposed according to one embodiment of the present specification;

FIG. 3 is a plan view of a structure in which light-emitting elements and lenses of a pixel of FIG. 1 are disposed according to one embodiment of the present specification;

FIG. 4 is a plan view of a structure in which a second electrode of a pixel of FIG. 1 is disposed according to one embodiment of the present specification;

FIGS. 5A to 5F are cross-sectional views illustrating a method of manufacturing an area taken along line A-A′ of FIG. 3 in accordance with an embodiment of the present specification; and

FIGS. 5G to 6 are cross-sectional views taken along line B-B′ of FIG. 4 according to one embodiment of the present specification.

### DETAILED DESCRIPTION

Advantages and features of the present specification, and methods of achieving them will become apparent with reference to preferable embodiments, which are described in detail, in conjunction with the accompanying drawings. However, the present specification is not limited to the embodiments to be described below and may be implemented in different forms, the embodiments are only provided to completely disclose the present disclosure and completely convey the scope of the present disclosure to those skilled in the art, and the present specification is defined by the disclosed claims.

Since the shapes, sizes, proportions, angles, numbers, and the like disclosed in the drawings for describing the embodiments of the present disclosure are only exemplary, the present disclosure is not limited to the illustrated items. The same reference numerals indicate the same components throughout the specification. Further, in describing the present disclosure, when it is determined that a detailed description of related known technology may unnecessarily obscure the gist of the present disclosure, the detailed description thereof will be omitted. When ‘including,’ ‘having,’ ‘comprising,’ and the like mentioned in the present specification are used, other parts may be added unless ‘only’ is used. A case in which a component is expressed in a singular form includes a plural form unless explicitly stated otherwise.

In interpreting the components, it should be understood that an error range is included even when there is no separate explicit description.

In the case of a description of a positional relationship, for example, when the positional relationship of two parts is described as ‘on,’ ‘at an upper portion,’ ‘at a lower portion,’ ‘next to, and the like, one or more other parts may be located between the two parts unless ‘immediately’ or ‘directly’ is used.

The first, the second, and so on are used to describe various components, but these components are not limited by these terms. These terms are used only to distinguish one component from another. Therefore, the first component referred to below may be a second component within the technical spirit of the present disclosure.

The same reference numerals indicate the same components throughout the specification.

The size and thickness of each component shown in the drawings are shown for convenience of description, and the present invention is not necessarily limited to the size and thickness of the components shown.

Any of the features of the various embodiments of the present invention may be partially or fully combined or combined with each other, and various interlocking and driving are technically possible as fully understood by a person skilled in the art, and each embodiment may be implemented independently with respect to each other or may be implemented together in a related relationship.

Hereinafter, display devices according to embodiments of the present specification will be described in detail with reference to the accompanying drawings.

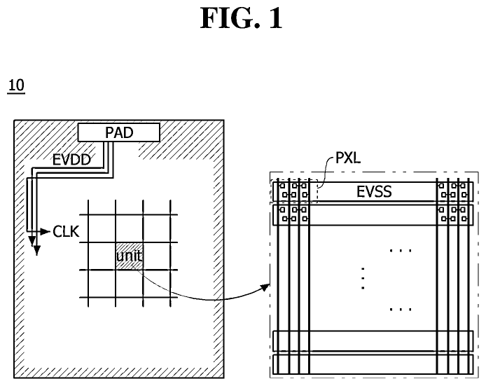

FIG. 1 is a plan view illustrating a display device according to an embodiment of the present specification.

Referring to FIG. 1, a display device 10 may include a display area in which an image is displayed, and a non-display area in which an image is not displayed, and a driving circuit and wirings for transmitting signals to the display area are disposed.

In the non-display area, the driving circuit may be mounted and a pad portion PAD to which an integrated circuit, a printed circuit, etc. are connected may be disposed.

A data driving circuit or a gate driving circuit may be disposed in the non-display area, and a controller signal for controlling a driving operation may be supplied to the non-display area.

The controller signal, which includes a variety of timing signals such as a clock signal CLK, an input data enable signal and synchronization signals, is received from the pad portion PAD.

The display device 10 may drive a light-emitting element through a pixel driving transistor connected to a driving voltage EVDD. The driving voltage (EVDD) may be a high potential voltage. The transistor includes a semiconductor element, a source/drain electrode, and a gate electrode, and the driving voltage EVDD is applied to the light-emitting element through a pixel electrode connected to the drain electrode. A high potential voltage wiring may be a pixel electrode or a first electrode connected to a driving transistor of each pixel PXL, and a common voltage wiring used to supply a common voltage EVSS may be a cathode electrode or a second electrode connected to a light-emitting element. The common voltage EVSS may be a low potential voltage EVSS.

In addition, a pixel driving circuit part on the substrate disposed on the display device 10 may drive pixels with a driving circuit chip. The pixel driving circuit part may drive a plurality of pixels by transmitting a signal from the driving circuit chip, such as a driving voltage, an image signal (digital signal), and a synchronization signal synchronized with the image signal, and outputting the driving voltage EVDD and the common voltage EVSS of the light-emitting element. The pixel driving circuit part may receive an image signal and a synchronization signal from a host system. The host system may include a main board of a wearable system, a mobile system, a television (TV) system, a tablet computer, a notebook computer, a navigation system, a personal computer (PC), etc.

A driving voltage electrode or a common voltage electrode may be commonly formed on a front surface of the display device.

This specification describes, but is not limited to, an example in which common voltage electrodes are commonly formed.

Referring to FIG. 1, the common voltage EVSS may be commonly disposed on the front surface of the display device or may be commonly disposed on each pixel PXL row, but is not limited thereto.

One pixel PXL may include one or more sub-pixels, for example, red, green, and blue sub-pixels.

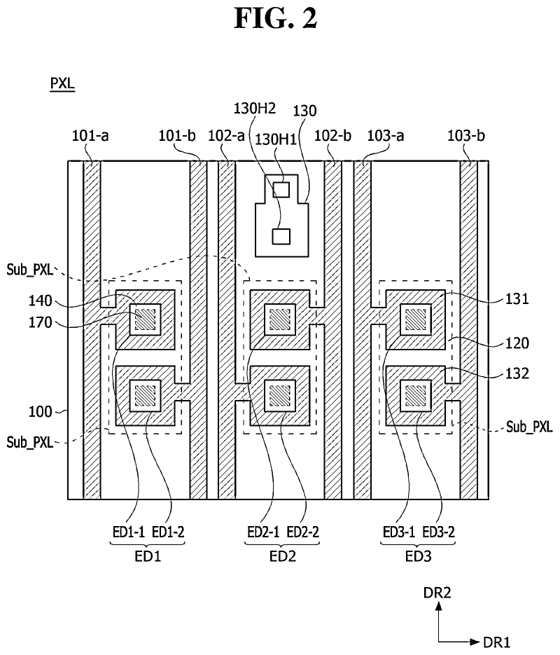

FIGS. 2 to 5A are enlarged plan views and cross-sectional views of the pixel PXL of FIG. 1.

The display device 10 may include a pixel driving circuit part 200, a buffer layer 110, planarization layers 111 and 112, and a plurality of wirings disposed on a substrate 100.

The substrate 100 may be made of plastic with flexibility. For example, the substrate 100 may be made of a single layer or multiple layers of a material such as polyimide, polyethylene terephthalate, polyethylene naphthalate, polycarbonate, polyethersulfone, polyarylate, polysulfone, and cyclic-olefin copolymer, but is not limited thereto. The substrate 100 may be made of glass.

The pixel driving circuit part 200 may be disposed on the substrate 100.

The pixel driving circuit part 200 may include a plurality of thin film transistors using an amorphous silicon semiconductor, a polycrystalline silicon semiconductor, or an oxide semiconductor, and at least one storage capacitor. The thin film transistors may include at least one driving thin film transistor, at least one switching thin film transistor, and the like. When a plurality of thin film transistors is included in the pixel driving circuit part 200, they may be formed on the substrate 100 by TFT manufacturing processes.

In addition, the pixel driving circuit part 200 may include a driving circuit chip.

The driving circuit chip may transmit a driving voltage for driving a light-emitting element, an image signal (digital signal), a synchronization signal synchronized with the image signal, etc. to the light-emitting element. If the pixel driving circuit part 200 is a driving circuit chip, an adhesive layer may be further disposed between the substrate 100 and the pixel driving circuit part 200.

The adhesive layer may be made of, but is not limited to, acrylic resin, silicone resin, etc.

The buffer layer 110 covering the pixel driving circuit part 200 may be disposed on the substrate 100. The buffer layer 110 may be made of, but is not limited to, an organic insulating material, such as photosensitive photo acryl or photosensitive polyimide.

In addition, the buffer layer 110 may be used by stacking an inorganic insulating material, for example, silicon nitride (SiNₓ) or silicon oxide (SiO₂) in a multiple layers, and may be used by stacking an organic insulating material and an inorganic insulating material in multiple layers.

The buffer layer 110 may surround a side surface of the pixel driving circuit part 200 and cover a portion of an upper surface. An opening exposing a portion of the pixel driving circuit part 200 may be disposed to expose a first contact electrode 210 and a second contact electrode 220 of the pixel driving circuit part 200.

The plurality of planarization layers 111 and 112 may be disposed on the buffer layer 110. The plurality of planarization layers 111 and 112 may be made of, but is not limited to, an organic insulating material, such as photosensitive photo acryl or photosensitive polyimide.

A plurality of contact holes may be formed in the plurality of planarization layers 111 and 112 so that a first connection wiring 230 and a third connection wiring 250 transmitting signals of the first contact electrode 210 of the pixel driving circuit part 200, and a second connection wiring 240 and a fourth connection wiring 260 transmitting signals of the second contact electrode 220 may be disposed on the first planarization layer 111 and the second planarization layer 112.

The first connection wiring 230, the second connection wiring 240, the third connection wiring 250, and the fourth connection wiring 260 may include at least one of titanium (Ti), molybdenum (Mo), aluminum (Al), and indium tin oxide (ITO) or indium zinc oxide (IZO).

A protrusion 120 may be disposed on the third and fourth connection wirings 250 and 260 and a portion of the second planarization layer 112.

The protrusion 120 may be made of, but is not limited to, an organic insulating material, such as photosensitive photo acryl or photosensitive polyimide.

The first connection electrode 131 and the second connection electrode 132 may be disposed on the upper surface and side surface of the protrusion 120.

The first connection electrode 131 and the second connection electrode 132 may be formed by the same process as the signal lines 101-a, 101-b, 102-a, 102-b, 103-a, and 103-b of FIG. 2, and may extend from the signal lines 101-a, 101-b, 102-a, 102-b, 103-a, and 103-b to be disposed on the upper surface and side surface of the protrusion 120.

The signal lines 101-a, 101-b, 102-a, 102-b, 103-a, and 103-b may be electrically connected to the fourth connection wiring 260 below to transmit a driving voltage EVDD from the driving circuit part 200 to the light-emitting element EM.

The signal lines 101-a, 101-b, 102-a, 102-b, 103-a, and 103-b may extend in a second direction DR2 and may be disposed between sub-pixels Sub_PXL, respectively.

The first connection electrode 131 and the second connection electrode 132 may be disposed to extend in a first direction DR1 that intersects the second direction DR2. Each sub-pixel Sub_PXL includes two light-emitting elements, and if one of the light-emitting elements has an abnormality or the light-emitting element is not transferred, the luminance of the other light-emitting element may be adjusted to prevent light-emitting efficiency from being lowered.

The signal lines 101-a, 101-b, 102-a, 102-b, 103-a, and 103-b are disposed on both sides of each sub-pixel Sub_PXL, and each sub-pixel Sub_PXL may include first light-emitting element areas ED1-1, ED2-1, and ED3-1 and second light-emitting element areas ED1-2, ED2-2, and ED3-2.

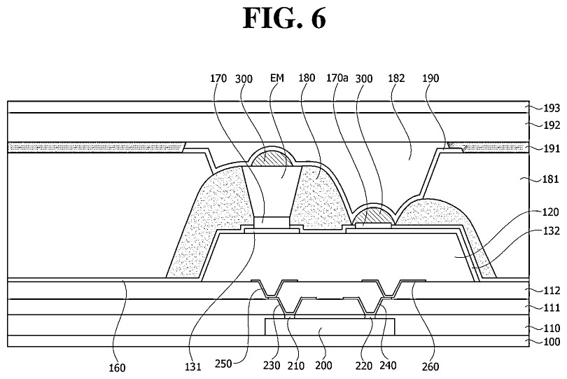

The third connection electrode 130 may be disposed on one side surface of the sub-pixel Sub_PXL between the signal lines 101-a, 101-b, 102-a, 102-b, 103-a, and 103-b. The third connection electrode 130 may be electrically connected to the third connection wiring 250 through a first contact hole 130H1 and may be connected to a second electrode 190 (see FIG. 6) through a second contact hole 130H2 to transmit a signal of the driving circuit part 200.

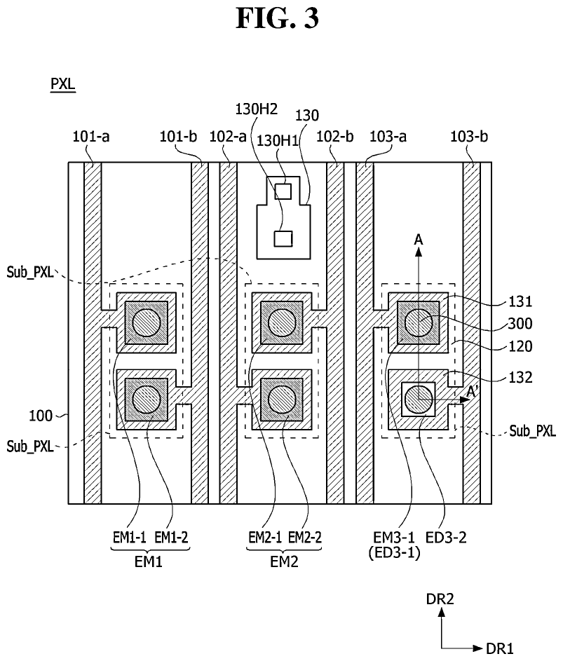

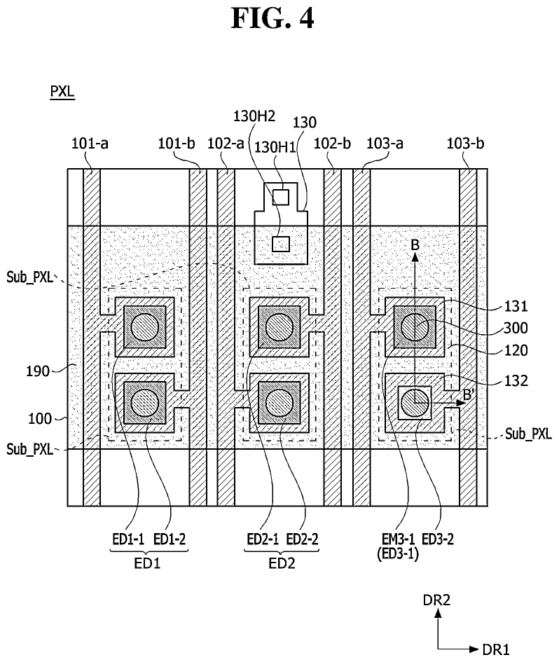

Referring to FIGS. 3 to 4, first light-emitting elements EM1-1, EM2-1, and EM3-1 and second light-emitting elements EM1-2 and EM2-2 may be disposed in the first light-emitting element areas ED1-1, ED2-1, and ED3-1 and the second light-emitting element areas ED1-2 and ED2-2.

For example, one pixel PXL may include light-emitting elements EM1, EM2, and EM3-1 of three colors. The first light-emitting element EM1 may be a red light-emitting element, the second light-emitting element EM2 may be a green light-emitting element, and the third light-emitting element EM3-1 may be a blue light-emitting element.

For example, the light-emitting element may not be transferred to an area where the light-emitting element is not transferred, for example, to the second light-emitting element area ED3-2 of the blue sub-pixel, among the plurality of sub-pixels Sub_PXL of the pixel PXL.

The lens 300 may be disposed on the first light-emitting elements EM1-1, EM2-1, and EM3-1 and the second light-emitting elements EM1-2 and EM2-2 and the second light-emitting element area ED3-2.

To connect an upper pad electrode and the second electrode 190 of the light-emitting element disposed on upper surfaces of the first light-emitting elements EM1-1, EM2-1, and EM3-1 and the second light-emitting elements EM1-2 and EM2-2, the lens 300 may be formed to have a short side length or less of the upper surfaces of the first light-emitting elements EM1-1, EM2-1, and EM3-1 and the second light-emitting elements EM1-2 and EM2-2.

For example, if the size of the upper surfaces of the first light-emitting elements EM1-1, EM2-1, and EM3-1 and the second light-emitting elements EM1-2 and EM2-2 is 10 μm*15 μm, the lens 300 may have a maximum diameter of less than 10 μm.

For example, a maximum area ratio occupied by the lens 300 on the upper portions of the first light-emitting elements EM1-1, EM2-1, and EM3-1 and the second light-emitting elements EM1-2 and EM2-2 may not exceed π/4. Here, π may represent the ratio of the circumference of a circle to its diameter.

The maximum size of the lens 300 for contacting of the second electrode 190 with the upper electrodes of the first light-emitting elements EM1-1, EM2-1, and EM3-1 and the second light-emitting elements EM1-2 and EM2-2 may be a size obtained by multiplying the upper areas of the first light-emitting elements EM1-1, EM2-1, and EM3-1 and the second light-emitting elements EM1-2 and EM2-2 by (1−π/4).

The lens 300 may include acrylate or siloxane as a polymer-based material.

The second electrode 190 may be disposed on the first light-emitting elements EM1-1, EM2-1, and EM3-1, the second light-emitting elements EM1-2 and EM2-2, and the lens 300.

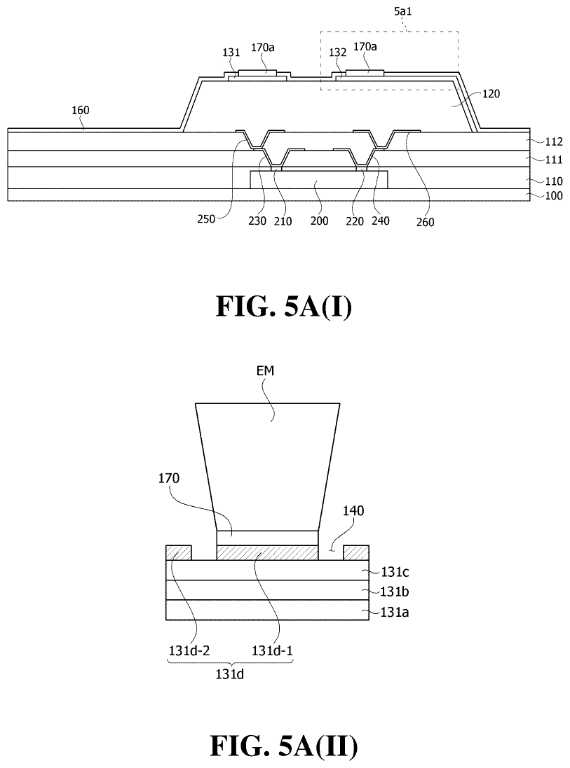

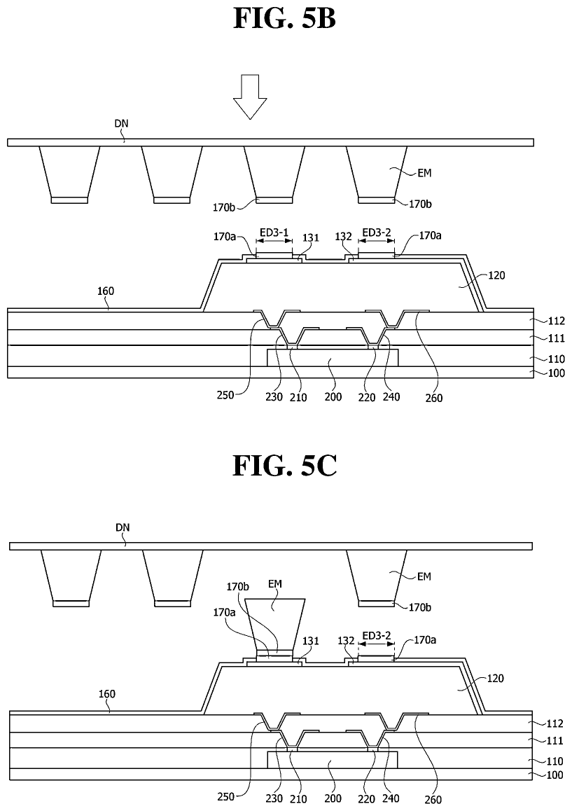

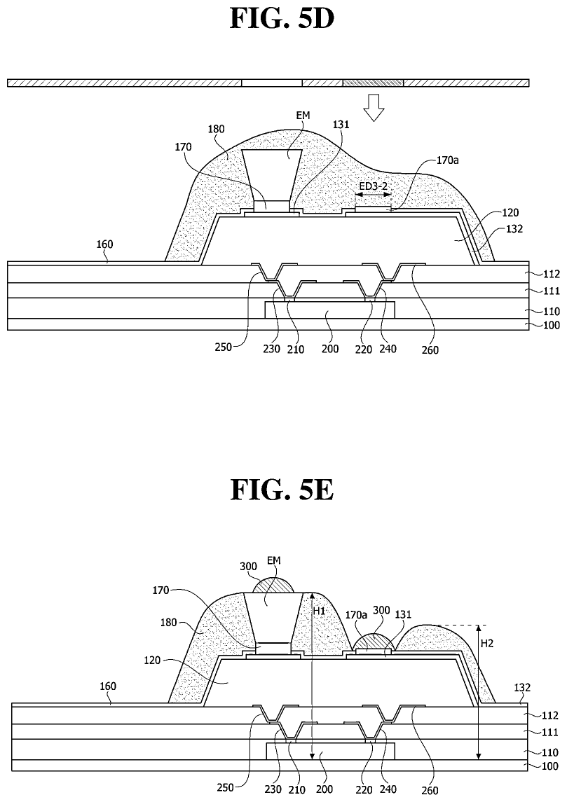

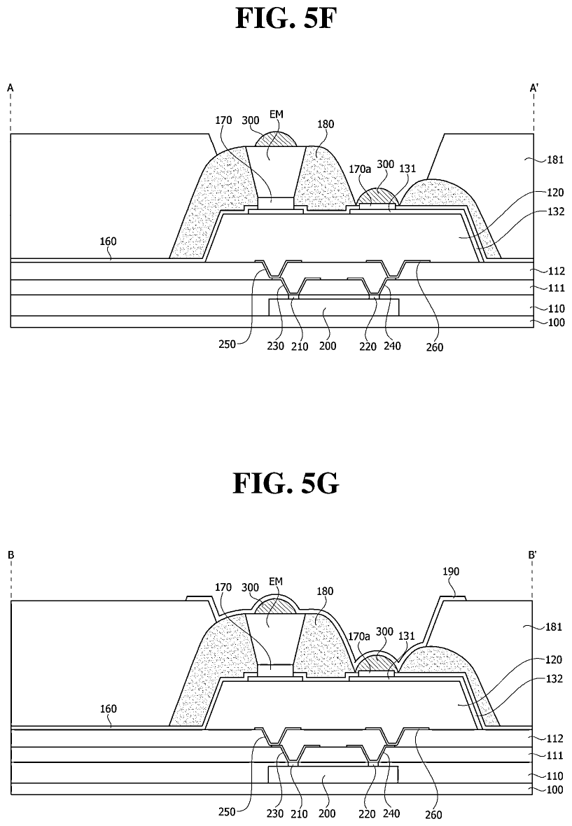

Part (I) of FIG. 5A to FIG. 5G are cross-sectional views illustrating a method of manufacturing an area taken along line A-A′ of FIG. 3 and line B-B′ of FIG. 4 in accordance with an embodiment of the present specification.

The first connection electrode 131 and the second connection electrode 132 may be disposed on the upper surface and side surface of the protrusion 120. Here, the first connection electrode 131 and the second connection electrode 132 may be collectively referred to as a first electrode to be connected to the light emitting element.

The first connection electrode 131 and the second connection electrode 132 may be a multilayer including titanium (Ti), molybdenum (Mo), aluminum (Al), indium tin oxide (ITO), and indium zinc oxide (IZO).

Part (II) of FIG. 5A is an enlarged cross-sectional view of a portion of the second connection electrode 132. The second connection electrode 132 may be formed in a multilayer structure including a first layer 131a, a second layer 131b, a third layer 131c, and a fourth layer 131d.

The first layer 131a, the second layer 131b, the third layer 131c, and the fourth layer 131d may include titanium (Ti), molybdenum (Mo), or aluminum (Al).

The fourth layer 131d may include a transparent conductive oxide layer such as indium tin oxide (ITO) or indium zinc oxide (IZO), having corrosion resistance, and acid resistance.

By removing a partial area of the fourth layer 131d in which the light-emitting element EM is not disposed, the fourth layer 131d may be divided into a fourth-first layer 131d-1 area in which the light-emitting element EM is disposed, and a fourth-second layer 131d-2 area in which the first layer 131a, the second layer 131b, and the third layer 131c are disposed.

The third layer 131c may be exposed in an area from which a portion of the fourth layer 131d is removed. The third layer 131c may increase the luminous efficiency by reflecting light upward from the light emitting-element EM, which performs top emission, using a metal material with high reflectivity such as aluminum (Al).

A protective layer 160 may be formed on the second planarization layer 112, the first connection electrode 131, the second connection electrode 132, and the protrusion 120. The protective layer 160 may be formed by stacking an inorganic insulating material, such as silicon nitride (SiNₓ) or silicon oxide (SiO₂), in a single layer or multiple layers.

The protective layer 160 on the fourth-first layer 131d-1 may be removed by a process of removing a portion of the fourth layer 131d and dividing the area into the fourth-first layer 131d-1 area in which the light-emitting element EM is disposed and the fourth-second layer 131d-2 area.

An adhesive layer 170 may be disposed on an area of the fourth-first layer 131d-1 from which the protective layer 160 is removed. An adhesive layer 170 may be made of, but is not limited to, indium (In), tin (Sn), metal paste, or an alloy thereof. Herein, the adhesive layer may also be referred to as a contact wiring when appropriate, and sometimes, it may also be simply referred to as a metal layer.

The light-emitting element EM formed on a single crystal substrate may be primarily transferred to a donor substrate DN and secondarily transferred to the substrate 100, which is an array substrate.

A plurality of light-emitting elements EM may be included in one donor substrate DN, and may be transferred to the first light-emitting element areas ED1-1, ED2-1, and ED3-1 and the second light-emitting element areas ED1-2, ED2-2, and ED3-2 areas on the protrusion 120.

The light-emitting element EM may have a different shape and size depending on the light-emitting efficiency for each sub-pixel Sub_PXL.

In addition, as shown, in the case of upper light emission, it may have an inverted tapered shape to increase the light emission efficiency, and in the case of lower light emission, it may have a trapezoidal shape, or a square shape.

The light-emitting element EM may be inorganic light-emitting diodes. The inorganic light-emitting diodes may have a size of 1 μm to 50 μm, or 1 μm to 20 μm in the horizontal direction (in the X-axis direction or Y-axis direction). The Inorganic light-emitting diodes may be referred to as micro light-emitting diodes. The inorganic light-emitting diode may include a p-doped semiconductor layer, an active layer (e.g., including one or more quantum well layers), and an n-doped semiconductor layer. Additionally, the inorganic light-emitting diode may include a first pad electrode connected to the p-doped semiconductor layer and a second pad electrode connected to the n-doped semiconductor layer. The inorganic light-emitting diodes may be manufactured using Group II-VI or Group III-V compound semiconductors. The inorganic light-emitting diode may be manufactured by a separate manufacturing process and may be disposed on a first adhesive layer 170a by a transfer process.

A second adhesive layer 170b (wherein the second adhesive layer may be also referred to as a first metal layer where proper) for increasing a contact force between the light-emitting element EM and the first adhesive layer 170a may be further disposed between the light-emitting element EM and the first adhesive layer 170a.

The second adhesive layer 170b may be, but is not limited to, an adhesive containing gold (Au), a metal paste, or a conductive material.

The first adhesive layer 170a and the second adhesive layer 170b are formed into the adhesive layer 170 by eutectic bonding to fix the light-emitting element EM.

The transfer method of the light-emitting element EM may use a laser and a stamping process, and the light-emitting element EM may be disposed in the light-emitting element area by such a transfer process. However, due to misalignment of the donor substrate DN and the substrate 100 or poor contact between the first adhesive layer 170a and the second adhesive layer 170b, the light-emitting element EM may be transferred to the first light-emitting element area ED3-1, and the light-emitting element EM may not be transferred to the second light-emitting element area ED3-2.

A laser transfer method may include lowering the donor substrate DN toward the substrate 100, aligning and contacting the light-emitting element EM with the first light-emitting element area ED3-1 and the second light-emitting element area ED3-2, and transferring the laser from an upper portion of the donor substrate DN to remove the adhesion between the donor substrate DN and the light-emitting element EM and allow the light-emitting element EM to be positioned and adhered on the first adhesive layer 170a and the second adhesive layer 170b of the first light-emitting element area ED3-1 and the second light-emitting element area ED3-2.

A stamping transfer method may include lowering the donor substrate DN toward the substrate 100, aligning and contacting the light emitting element EM with the first light emitting element area ED3-1 and the second light emitting element area ED3-2, and pressing the donor substrate DN toward the substrate 100 at a low temperature to allow the light-emitting element EM to be positioned and adhered on the first adhesive layer 170a and the second adhesive layer 170b of the first light-emitting element area ED3-1 and the second light-emitting element area ED3-2.

A first insulating layer 180 may be disposed on the first light-emitting element area ED3-1, the second light-emitting element area ED3-2, and the protrusion 120. The first insulating layer 180 may be made of an organic insulating material, and may further include scattering particles such as titanium dioxide to reflect or diffuse light as materials to improve the light efficiency of the light-emitting element EM. The first insulating layer 180 may disposed to surround the first light-emitting element area ED3-1 and the second light-emitting element area ED3-2, thereby improving a light emission effect.

The first insulating layer 180 is disposed on the protrusion 120 on which the light-emitting element EM is disposed and surrounds the side and upper surfaces of the protrusion 120.

The first insulating layer 180 may be formed to have a high thickness of 1 μm to 60 μm, or 1 μm to 30 μm, to surround the protrusion 120 and the light-emitting element EM.

The heights of the first light-emitting element area ED3-1 and the first insulating layer 180 may be formed to be different from each other due to the non-transfer of the light-emitting element EM to the second light-emitting element area ED3-2.

To connect the second electrode 190 and the light-emitting element EM, an upper second pad electrode of the light-emitting element EM may be exposed. A portion of the first insulating layer 180 in the first light-emitting element area ED3-1 and the second light-emitting element area ED3-2 may be removed by a masking process.

Through this masking process, the first insulating layer 180 in the second light-emitting element area ED3-2 may be removed to expose the first adhesive layer 170a.

A lens 300 may be formed on an upper second pad electrode of the light-emitting element EM and on the first adhesive layer 170a in the second light-emitting element area ED3-2.

The lens 300 may form an organic insulating film material on the substrate and form a micro-part lens shape by a masking process. The lens 300 is a polymer-based material, which is a photo material, and may include acrylate or siloxane.

The lens 300 may be formed to be equal to or larger than the area of the first adhesive layer 170a of the second light-emitting element area ED3-2. In this way, the second electrode 190 disposed on the upper portion of the lens 300 does not contact that adhesive layer.

When the second electrode 190 disposed on an upper portion of the lens 300 is connected to the first adhesive layer 170a, a short may occur due to the electrical connection.

In addition, the lens 300 may be formed to have an area smaller than an upper surface of the second pad electrode of the light-emitting element EM. A minimum area not overlapping the lens 300 may be required on an upper surface of the light-emitting element EM so that the light-emitting element EM and the second electrode 190 disposed on the lens 300 of the upper portion of the light emitting element EM may be electrically connected to the second pad electrode of the upper portion of the light emitting element EM.

For example, if an area of the upper surface of the light-emitting element EM is 10 μm*15 μm, a maximum diameter of the lens 300 may be less than 10 μm.

For example, a maximum area ratio occupied by the lens 300 in the upper portion of the light emitting element EM may not exceed π/4, and a maximum size of the lens 300 for contact between the second electrode 190 and an upper electrode of the light emitting element EM may be a size obtained by multiplying an upper area of the light emitting element EM by (1−π/4). Here, π may represent the ratio of the circumference of a circle to its diameter.

The first insulating layer 180 may have a first height H1 of the uppermost surface of the first insulating layer 180 of the first light-emitting element area ED3-1 from the upper surface of the substrate 100, and a second height H2 of the uppermost surface of the first insulating layer 180 of the second light-emitting element area ED3-2 from the upper surface of the substrate 100.

The first height H1 may be higher than the second height H2.

A second insulating layer 181 may be formed on an upper portion of the substrate 100 and on a side surface of the first insulating layer 180.

The second insulating layer 181 may planarize an upper surface and may be disposed to surround the side surface of the first insulating layer 180.

The second insulating layer 181 may be formed of an organic insulating material, and may be made of, but is not limited to, siloxane, photosensitive photo acryl, or photosensitive polyimide.

A second contact hole 130H2 may be formed in the second insulating layer 181 to expose a third connection electrode 130.

The second electrode 190 may be disposed on the second contact hole 130H2, the lens 300, the light-emitting element EM, the first insulating layer 180, and the second insulating layer 181.

The second electrode 190 may be electrically connected to the third connection electrode 130 to transmit a driving voltage EVDD or a common voltage EVSS to the light-emitting element EM.

On the second electrode 190, a third insulating layer 182 (see FIG. 6) may be disposed in an opening area of the first insulating layer 180 formed on the upper portion of the light-emitting element EM and the lens 300. The third insulating layer 182 may further include scattering particles such as titanium dioxide in the organic insulating material. The third insulating layer 182 may be formed of the same material as the first insulating layer 180, and may reflect or diffuse light as a material for improving the light efficiency of the light-emitting element EM, and may planarize the upper surface thereof.

FIG. 6 is a cross-sectional view taken along line B-B′ of FIG. 4 according to one embodiment.

A light blocking layer 191 may be disposed on the second insulating layer 181, the second electrode 190, and the third insulating layer 182 on which the light-emitting element EM is not disposed.

The light blocking layer 191 may be disposed on the entire surface of the substrate on which the light-emitting element EM is not disposed, and the light blocking layer 191 may be formed by filling the second contact hole 130H2.

The light blocking layer 191 may be formed of, but is not limited to, an organic material including a black material.

A fourth insulating film 192 and a protective film may be further disposed on the second electrode 190 and the light blocking layer 191, and a touch part including a touch electrode for driving a touch may be disposed on the protective film.

In addition, if necessary, a color filter may be additionally disposed in an area corresponding to the light-emitting element, but is not limited thereto.

An upper substrate 193 for protecting the display device may be disposed on the fourth insulating film 192.

The upper substrate 193 may be made of a single layer or multiple layers of materials such as, but is not limited to, glass, polyimide, polyethylene terephthalate, polyethylene naphthalate, polycarbonate, polyethersulfone, polyarylate, polysulfone, and cyclic-olefin copolymer. A display device according to embodiments of the present specification may be described as follows.

A display device according to embodiments of the present specification may be described as follows.

A display device according to embodiments of the present specification may include: a substrate including a display area and a non-display area; a driving circuit part disposed in the display area on the substrate; a plurality of planarization layers disposed on the driving circuit part; and a plurality of pixels disposed on the plurality of planarization layers in the display area, wherein the plurality of pixels may include a plurality of first light-emitting element areas and a plurality of second light-emitting element areas, a first insulating layer may be disposed in the first light-emitting element area and the second light-emitting element area, and the first insulating layer may have different heights in the first light-emitting element area and the second light-emitting element area.

According to some embodiments of the present specification, a height of the first insulating layer may include a first height from an upper surface of the substrate to the uppermost surface of the first insulating layer disposed in the first light-emitting element area, and a second height from the upper surface of the substrate to the uppermost surface of the first insulating layer disposed in the second light-emitting element area.

According to some embodiments of the present specification, the first height may be higher than the second height.

According to some embodiments of the present specification, the plurality of pixels may include a plurality of sub-pixels, and each sub-pixel may include at least one protrusion.

According to some embodiments of the present specification, the first light-emitting element area and the second light-emitting element area may be disposed on the at least one protrusion.

According to some embodiments of the present specification, below the at least one protrusion, a first connection wiring may be disposed corresponding to the first light-emitting element area, and a second connection wiring may be disposed corresponding to the second light-emitting element area.

According to some embodiments of the present specification, a first connection electrode may be disposed on the first connection wiring, and a second connection electrode may be disposed on the second connection wiring.

According to some embodiments of the present specification, a first light-emitting element may be disposed on the first connection electrode.

According to some embodiments of the present specification, the display device includes a lens disposed on the first light-emitting element and a lens disposed on the second connection electrode.

According to some embodiments of the present specification, a second electrode may be disposed on the lens and the first insulating layer.

According to some embodiments of the present specification, the display device may further include a second insulating layer disposed on the second electrode.

According to some embodiments of the present specification, the second insulating layer may be formed of a same material as the first insulating layer, and/or may have a planar upper surface.

A method of manufacturing a display device according to embodiments of the present specification may include: preparing a substrate including a display area and a non-display area; forming a driving circuit part and a plurality of planarization layers on the substrate; forming a protrusion on the plurality of planarization layers; forming a first connection electrode and a second connection electrode in a first light-emitting element area and a second light-emitting element area disposed on the protrusion; disposing a light-emitting element on one of the first connection electrode and the second connection electrode; and disposing a lens respectively on an upper portion of the other one of the first connection electrode and the second connection electrode and on an upper portion of the light-emitting element, wherein a first insulating layer may be disposed on the first light-emitting element area and the second light-emitting element area.

According to some embodiments of the present specification, said disposing the light-emitting element may include: performing a laser transfer or a stamping transfer from a donor substrate to the prepared substrate.

According to some embodiments of the present specification, the first insulating layer may have a first height from an upper surface of the substrate to the uppermost surface of the first insulating layer disposed in the first light-emitting element area, and a second height from the upper surface of the substrate to the uppermost surface of the first insulating layer disposed in the second light-emitting element area.

According to some embodiments of the present specification, the first height may be formed to be higher than the second height.

According to some embodiments of the present specification, an adhesive layer is formed on the first connection electrode and the second connection electrode.

According to some embodiments of the present specification, the lens may be formed to be equal to or larger than an area of the adhesive layer.

A display device according to embodiments of the present specification may include: a substrate including a display area and a non-display area; a driving circuit part disposed on the substrate; a plurality of planarization layers disposed on the driving circuit part; and a plurality of pixels disposed on the plurality of planarization layers in the display area, wherein the plurality of pixels may include a plurality of first light-emitting element areas and second light-emitting element areas, wherein a first connection electrode, a first light-emitting element disposed on the first connection electrode, a first lens disposed on the first light-emitting element, and a second electrode disposed on the first lens may be disposed in the first light-emitting element area, and a second connection electrode, a second lens disposed on the second connection electrode, and a second electrode disposed on the second lens may be disposed in the second light-emitting element area.

According to some embodiments of the present specification, the second connection electrode and the second electrode may be physically and electrically separated by the second lens, that is, may do not contact with each other due to the second lens.

According to some embodiments of the present specification, the second connection electrode and the second electrode are not contacted by the lens.

According to some embodiments of the present specification, a protective layer may be disposed on the second connection electrode so that a portion of the second connection electrode is exposed, a contact wiring may be disposed on the exposed portion of the second connection electrode, and the second lens may cover the contact wiring.

According to some embodiments of the present specification, an area of the lens is larger than an area of the contact wiring and smaller than an area of an upper surface of the second light-emitting element.

The embodiments of the present specification have been described in more detail with reference to the accompanying drawings, but the present specification may not necessarily limited to these embodiments, and may be variously modified without departing from the technical spirit of the present invention. Therefore, the embodiments disclosed in the present specification are not intended to limit the technical spirit of the present invention, but to explain, and the scope of the technical spirit of the present invention is not limited by these embodiments. Therefore, it should be understood that the embodiments described above are illustrative in all respects and not restrictive. The scope of protection of the present invention should be interpreted by the following claims, and all technical spirits within the equivalent range should be interpreted as being included in the scope of the present specification.

[Description of reference numerals]

| | |
|---|---|
| 100: Substrate | 200: Pixel driving circuit part |
| 110: Buffer layer | 111: First planarization layer |
| 112: Second planarization layer | 120: Protrusion |
| ED1, ED2, ED3: Light-emitting | |
| element areas | |
| 191: Light blocking layer | 160: Protective layer |
| 170: Adhesive layer | 180: First insulation layer |
| 181: Second insulation layer | 182: Third insulation layer |
| 190: Second electrode | |

What is claimed is:

1. A display device comprising:
a substrate including a display area and a non-display area;
a driving circuit part in the display area on the substrate;
a plurality of planarization layers on the driving circuit part; and
a plurality of pixels on the plurality of planarization layers in the display area,
wherein the plurality of pixels include a plurality of first light-emitting element areas and a plurality of second light-emitting element areas,
a first insulating layer in a first light-emitting element area from the plurality of first light-emitting element areas and a second light-emitting element area from the plurality of second light-emitting element areas,
wherein the first insulating layer has different heights in the first light-emitting element area and the second light-emitting element area.

2. The display device of claim 1, wherein a height of the first insulating layer includes a first height from an upper surface of the substrate to an uppermost surface of the first insulating layer in the first light-emitting element area, and a second height from the upper surface of the substrate to the uppermost surface of the first insulating layer in the second light-emitting element area.

3. The display device of claim 2, wherein the first height is higher than the second height.

4. The display device of claim 1, wherein the plurality of pixels include a plurality of sub-pixels, and
each of the plurality of sub-pixels includes at least one protrusion.

5. The display device of claim 4, wherein the plurality of first light-emitting element areas and the plurality of second light-emitting element areas are on the at least one protrusion.

6. The display device of claim 5, wherein below the at least one protrusion, a first connection wiring corresponds to the first light-emitting element area and a second connection wiring corresponds to the second light-emitting element area.

7. The display device of claim 6, wherein a first connection electrode is on the first connection wiring and a second connection electrode is on the second connection wiring.

8. The display device of claim 7, wherein a first light-emitting element is on the first connection electrode.

9. The display device of claim 8, further comprising:
a lens on the first light-emitting element and a lens on the second connection electrode.

10. The display device of claim 9, wherein a second electrode is on the lenses and the first insulating layer.

11. The display device of claim 10, further comprising:
a second insulating layer on the second electrode.

12. The display device of claim 11, wherein the second insulating layer includes a same material as the first insulating layer and/or has a planar upper surface.

13. A method of manufacturing a display device, comprising:
preparing a substrate including a display area and a non-display area;
forming a driving circuit part and a plurality of planarization layers on the substrate;
forming a protrusion on the plurality of planarization layers;
forming a first connection electrode and a second connection electrode in a first light-emitting element area and a second light-emitting element area on the protrusion;
disposing a light-emitting element on one of the first connection electrode and the second connection electrode; and
disposing a lens respectively on an upper portion of another one of the first connection electrode and the second connection electrode and on an upper portion of the light-emitting element,
wherein a first insulating layer is on the first light-emitting element area and the second light-emitting element area.

14. The method of claim 13, wherein disposing the light-emitting element includes:
performing laser transfer or stamping transfer from a donor substrate to the prepared substrate.

15. The method of claim 13, wherein the first insulating layer has a first height from an upper surface of the substrate to an uppermost surface of the first insulating layer disposed in the first light-emitting element area, and a second height from the upper surface of the substrate to the uppermost surface of the first insulating layer disposed in the second light-emitting element area.

16. The method of claim 15, wherein the first height is formed higher than the second height.

17. The method of claim 13, wherein an adhesive layer is formed on the first connection electrode and the second connection electrode.

18. The method of claim 17, wherein the lens is formed to be equal to or larger than an area of the adhesive layer.

19. A display device comprising:
a substrate including a display area and a non-display area;
a driving circuit part on the substrate;
a plurality of planarization layers on the driving circuit part; and
a plurality of pixels on the plurality of planarization layers in the display area, the plurality of pixels including a plurality of first light-emitting element areas and a plurality of second light-emitting element areas,
a first connection electrode, a first light-emitting element on the first connection electrode, a first lens on the first light-emitting element, and a second electrode on the first lens are in a first light-emitting element area from the plurality of first light-emitting element areas, and
a second connection electrode, a second lens on the second connection electrode, and a second electrode on the second lens are in a second light-emitting element area from the plurality of second light-emitting element areas.

20. The display device of claim 19, wherein the second connection electrode and the second electrode do not contact with each other due to the second lens.

21. The display device of claim 19, further comprising:
a protective layer on the second connection electrode such that a portion of the second connection electrode is exposed; and
a contact wiring on the exposed portion of the second connection electrode, wherein the second lens covers the contact wiring.

22. The display device of claim 21, wherein an area of the second lens is larger than an area of the contact wiring and smaller than an area of an upper surface of a second light-emitting element.
